(19) United States
(12) Patent Application Publication
(10) Pub. No.: US 2011/0147873 A1
(43) Pub. Date: Jun. 23, 2011

(54) OPTICAL SEMICONDUCTOR DEVICE, AND OPTICAL PICKUP DEVICE AND ELECTRONIC DEVICE USING THE OPTICAL SEMICONDUCTOR DEVICE

(75) Inventors: Hideo FUKUDA, Kyoto (JP); Kouji Ise, Osaka (JP); Shinichi Miyamoto, Kyoto (JP)

(73) Assignee: PANASONIC CORPORATION, Osaka (JP)

(21) Appl. No.: 13/037,936

(22) Filed: Mar. 1, 2011

Related U.S. Application Data
(63) Continuation of application No. PCT/JP2009/006934, filed on Dec. 16, 2009.

(30) Foreign Application Priority Data
Jun. 22, 2009 (JP) 2009-147461

(51) Int. Cl. H01L 31/0216

(52) U.S. Cl. 257/434; 257/E31.119

(57) ABSTRACT

A semiconductor substrate is bonded to a glass board in a peripheral portion of the semiconductor substrate by an adhesive layer. A hollow region is formed in a portion surrounded by the semiconductor substrate, the glass board, and the adhesive layer. In the hollow region, reinforcing adhesive layers are formed on a back surface of the semiconductor substrate and at positions corresponding to bumps provided at regular intervals. The reinforcing adhesive layers allow the semiconductor substrate to have strength withstanding to a load of a testing probe.

### CROSS-REFERENCE TO RELATED APPLICATION

This is a continuation of PCT International Application PCT/JP2009/006934 filed on Dec. 16, 2009, which claims priority to Japanese Patent Application No. 2009-147461 filed on Jun. 22, 2009. The disclosures of these applications including the specifications, the drawings, and the claims are hereby incorporated by reference in their entirety.

### BACKGROUND

The present disclosure relates to optical semiconductor devices using chip size packages, and more particularly to optical semiconductor devices reducing physical stress applied to bump portions in testing to reduce stress cracking; and optical pickup devices and electronic devices using the optical semiconductor devices.

In recent years, with higher integration and higher function of semiconductor integrated circuit devices, circuit scale has been and is being increased, thereby leading to an increase in sizes of semiconductor chips, which in turn leads to an increase in sizes of semiconductor package. On the other hand, miniaturization of electronic devices has progressed and is progressing, the size of a semiconductor package to an electronic device is becoming a problem.

A light-receiving amplifier circuit for an optical pickup device includes an amplifier of several channels, which receives at a plurality of light-receiving elements, reflected light generated by irradiating an optical disc medium such as a compact disc (CD), a digital versatile disc (DVD), and a Blu-ray disc (BD) with laser light; converts a photocurrent to a voltage, and outputs the voltage.

An infrared laser element is used for a CD, a red laser element is used for a DVD, and a blue-violet laser element is used for a BD as light sources. In recent years, monolithic two-wavelength laser elements have been widely used, in which laser elements of two wavelengths of infrared and red laser are monolithically formed. In such a monolithic two-wavelength laser element, light-emitting positions are provided at predetermined intervals and two types of optical axes exist. It is thus necessary at a light-receiving side to provide dedicated light-receiving elements and amplifier circuits corresponding to the wavelengths on the same semiconductor substrate, thereby increasing a channel number of an amplifier. Furthermore, correspondence to BDs is also necessary, thereby further increasing the channel number of the amplifier. This increases the size of the semiconductor chip and a package for molding the semiconductor chip is becoming no more tolerable with a conventional size. In particular, where the device corresponds to BDs, the used wavelength is blue-violet light around 405 nm, which easily causes chemical changes, and thus, careful attention need to be paid for members used inside the package.

Thus, in recent years, chip size package (hereinafter abbreviated as “CSP”) has been proposed as a structure with a reduced package size. Specifically, an optical semiconductor chip appeared, which includes electrodes penetrating from the front surface to the back surface of a semiconductor substrate, and rewirings and bumps as electrode terminals on the back surface of the semiconductor substrate (see Japanese Patent Publication No. 2006-228837).

### SUMMARY

When testing electrical characteristics of an optical semiconductor device having a CSP structure, a testing probe is pressed on all of bumps provided on a back surface of a semiconductor substrate at the same time to obtain electrical contact between the bumps and the testing probe. Thus, the load of the testing probe is applied to each of the bumps. This load is also applied to the semiconductor substrate, and is absorbed only by the semiconductor substrate. As a result, the semiconductor substrate cannot withstand the load of the testing probe, and cracks occur around the bumps of the semiconductor substrate. In a worst case, the semiconductor substrate may be broken. Even when terminals projecting from the substrate surface like the bump terminals are not used, the substrate may be broken by a probe load in a testing with a probe.

For further miniaturization of a CSP in the future, a CSP structure with hardness, a reduced size, and a reduced thickness is needed.

Since direction recognition of a package becomes difficult in set mounting in accordance with miniaturization of a package, there is the problem that the package may be mounted in an opposite direction.

In view of the problems, it is an objective of the present disclosure to provide a highly reliable optical semiconductor device, in which a semiconductor substrate is not broken by the load of a testing probe in CSP testing, an optical semiconductor device in which a direction of the package is easily recognized, and an optical pickup device and an electronic device using the semiconductor device.

In order to solve the problems, an optical semiconductor device according to the present disclosure includes a semiconductor substrate including an active element on a first main surface; a plurality of electrode terminals formed on another main surface of the semiconductor substrate; a light-transmissive member provided on the first main surface to face the active element with a space interposed therebetween; a sealing portion formed in a peripheral portion of the first main surface; a hollow region formed on the first main surface among the active element, the light-transmissive member, and the sealing portion; and buffer portions formed in at least one portion of the hollow region.

According to this structure, the buffer portions, which disperse the load of the testing probe, are provided not only in the peripheral portion of the semiconductor substrate but also in the hollow region. This reduces breakage of the semiconductor substrate caused by the load of the testing probe.

Furthermore, in order to improve direction recognition of the package, at least one of the buffer portions near a corner of the semiconductor substrate may have a different form from the other buffer portions, or no buffer portion may be provided in a place for providing at least one of the buffer portions near the corner of the semiconductor substrate.

The present disclosure is advantageous in providing a highly reliable and miniaturized optical semiconductor device, in which a semiconductor substrate is not broken by the load of a testing probe in CSP testing, an optical semiconductor device in which a direction of the package is easily recognized, and an optical pickup device and an electronic device using the optical semiconductor device.

### BRIEF DESCRIPTION OF THE DRAWINGS

FIG. 1 is a top view illustrating the structure of an optical semiconductor device according to a first embodiment of the present disclosure.

FIG. 2 is a cross-sectional view taken along the line II-II of FIG. 1.

FIG. 3 is a cross-sectional view illustrating the structure of another optical semiconductor device according to the first embodiment of the present disclosure.

FIG. 4 is a top view illustrating the structure of an optical semiconductor device according to a second embodiment of the present disclosure.

FIG. 5 is a top view illustrating the structure of an optical semiconductor device according to a third embodiment of the present disclosure.

FIG. 6 is a top view illustrating the structure of another optical semiconductor device according to the third embodiment of the present disclosure.

FIG. 7 is a top view illustrating the structure of still another optical semiconductor device according to the third embodiment of the present disclosure.

FIG. 8 is a top view illustrating the structure of still another optical semiconductor device according to the third embodiment of the present disclosure.

FIG. 9 is a top view illustrating the structure of an optical semiconductor device according to a fourth embodiment of the present disclosure.

FIG. 10 is a cross-sectional view taken along the line X-X of FIG. 9.

FIG. 11 is a top view illustrating the structure of an optical pickup device according to a fifth embodiment of the present disclosure.

### DETAILED DESCRIPTION

Embodiments of the present disclosure will be described hereinafter with reference to the drawings.

### First Embodiment

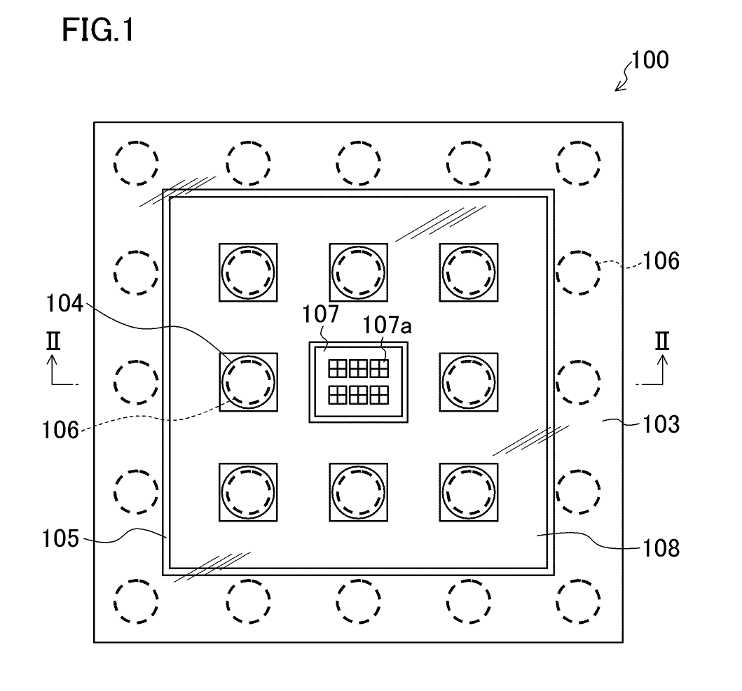

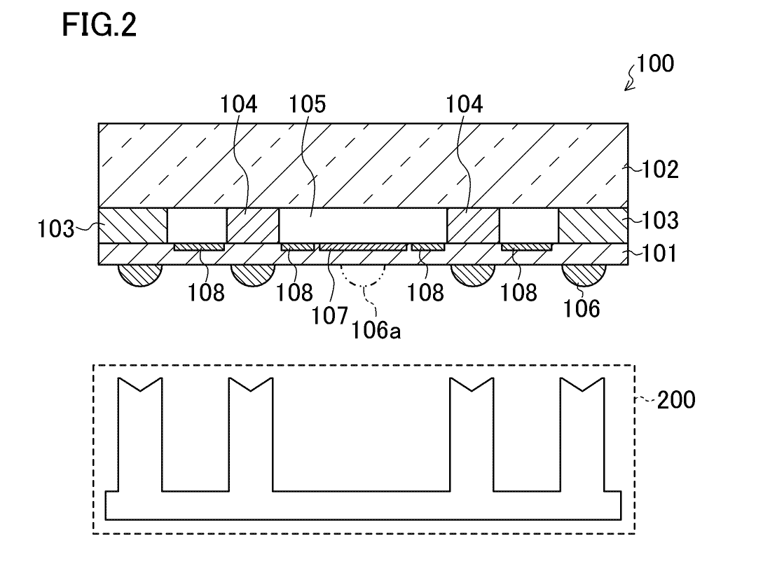

FIG. 1 is a top view illustrating an optical semiconductor device according to a first embodiment of the present disclosure. FIG. 2 is a cross-sectional view illustrating the optical semiconductor device of the first embodiment and a testing probe used in testing the optical semiconductor device. As shown in FIGS. 1 and 2, an optical semiconductor device 100 includes a semiconductor substrate 101, a protective glass board (light-transmissive member) 102, an adhesive layer 103 as a sealing portion, reinforcing adhesive layers 104 as buffer portions, and bumps 106 as electrode terminals. Note that the semiconductor substrate 101 is made of silicon and has a thickness of 100 μm, for example.

A light-receiving region 107 and signal processing circuits 108 are formed in a surface (a first main surface) of the semiconductor substrate 101. A plurality of light-receiving elements 107a receiving optical signals and generating photocurrents are provided in the light-receiving region 107. The semiconductor substrate 101 is bonded to the glass board 102 in a peripheral portion of the semiconductor substrate 101 by the adhesive layer 103. A hollow region 105 is formed in a portion surrounded by the semiconductor substrate 101, the glass board 102, and the adhesive layer 103.

When the adhesive layer 103 is bonded onto the light-receiving region 107, light transmittance decreases due to optical characteristics of the adhesive layer 103. Alternately, when irradiating blue-violet laser light with a wavelength around 405 nm, physical properties of the adhesive layer 103 particularly changes to cause a change in color or deformation. Thus, the adhesive layer 103 is not preferably formed on the light-receiving region 107. Also, when the adhesive layer 103 is bonded onto the signal processing circuits 108, stress caused by curing the adhesive layer 103 shifts values of resistors and capacitors which are passive elements, thereby shifting characteristics of transistors and diodes which are active elements. It is thus also not preferable to form the adhesive layer 103 on the signal processing circuits 108. Therefore, in order to reduce degradation of the characteristics, the adhesive layer 103 is not bonded onto the light-receiving region 107 or the signal processing circuits 108, and the hollow region 105 is provided.

The reinforcing adhesive layers 104 are formed in the hollow region 105 at positions corresponding to the respective bumps 106, which are provided at regular intervals. The area of the reinforcing adhesive layers 104 bonded to the semiconductor substrate 101 is larger than the area of the bumps 106 jointed to the semiconductor substrate 101. That is, the bumps 106 provided on a back surface (another main surface) of the semiconductor substrate 101 are positioned within the hollow region 105 of the surface of the semiconductor substrate 101, the reinforcing adhesive layers 104 are formed on the same positions as those of the bumps 106 on the surface of the semiconductor substrate 101. Note that a bump 106a is preferably not provided directly below the light-receiving region 107.

When testing the optical semiconductor device 100 having a CSP structure including the hollow region 105, a testing probe 200 is pressed on the bumps 106 provided on the back surface of the optical semiconductor device 100 to obtain electrical contact between the bumps 106 and the testing probe 200. Thus, the load (e.g., 50 grams per probe) of the testing probe 200 is applied to the bumps 106.

In FIG. 1, since eight bumps 106 are included in the hollow region 105, a load of 50 grams×8=400 grams in total is applied to the semiconductor substrate 101 in the hollow region 105. When the hollow region 105 applied with the load of 400 grams is supported only by the adhesive layer 103 formed in a peripheral portion of the semiconductor substrate 101, cracks occur in the semiconductor substrate 101 for lack of strength, or in a worst case, the semiconductor substrate 101 may be broken. In order to reduce the breakage due to the load of the testing probe 200, the reinforcing adhesive layers 104 for supporting the semiconductor substrate 101 are formed directly above the eight bumps 106.

The reinforcing adhesive layers 104 allow the semiconductor substrate 101 to have strength withstanding the load of the testing probe 200. Furthermore, even when the reinforcing adhesive layers 104 are misaligned from the positions directly above the bumps 106 due to mask misalignment, the sizes of the reinforcing adhesive layers 104 are preferably formed larger than those of the bumps 106 to reliably obtaining the strength of the semiconductor substrate 101.

Moreover, according to the first embodiment, since there are the reinforcing adhesive layers 104, bond strength between the semiconductor substrate 101 and the glass board 102 does not become problematic even when the area of the adhesive layer 103 is reduced. This reduces the chip size.

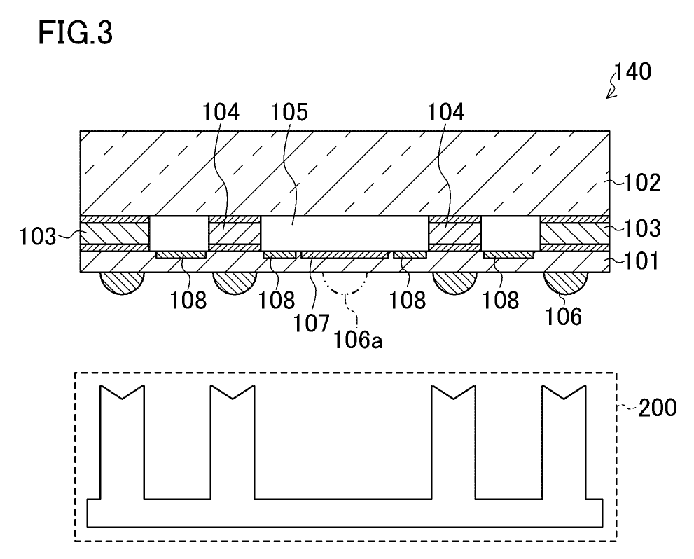

In the first embodiment, the adhesive layer 103 and the reinforcing adhesive layers 104 are used for the sealing portion and the buffer portions, respectively. However, as shown in an optical semiconductor device 140 in FIG. 3, similar advantages can be provided even when structures, which include a ceramic which is e.g., an insulator as a supporting body and adhesive layers above and below the ceramic, are used as a sealing portion 103 and buffer portions 104. Note that the sealing portion 103 and the buffer portions 104 are preferably formed in the same manufacturing step to simplify manufacturing steps and reduce costs.

While an example has been described where the bumps 106 projecting from the substrate are used as CSP back surface terminals, flat terminals also provide similar advantages in view of reducing substrate breakage in probe testing.

### Second Embodiment

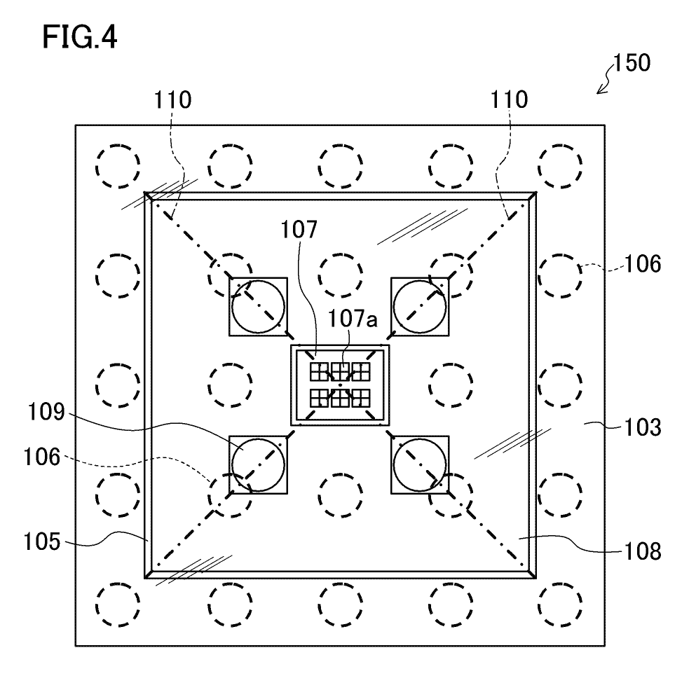

FIG. 4 is a top view illustrating an optical semiconductor device 150 according to a second embodiment of the present disclosure. This embodiment differs from the first embodiment in the position of the buffer portion, and accordingly, the position of the signal processing circuits 108. Furthermore, in the second embodiment, metal layers formed by plating or deposition are used on the substrate as buffer portions. The thickness of the metal layers is equal to or smaller than the thickness of the adhesive layer used for the sealing portion. The purpose of providing the buffer portions is to disperse the load of the testing probe as described above, the buffer portions are not necessarily bonded to the glass board facing the semiconductor substrate, as long as deformation of the semiconductor substrate caused by the load is reduced.

Metal plated layers 109 which are metal layers are provided in four portions of the hollow region 105 in a diagonal line indicated by an auxiliary line 110, at the same distances from the center of the hollow region 105 in a radial fashion, and at positions so that the total load of the testing probe is equally dispersed.

While the buffer portions have been described as the metal plated layers 109, the buffer portions are not limited thereto and may be made of any material, as long as deformation of semiconductor substrate caused by load is reduced. For example, the objective of the present disclosure is achieved even with a ceramic or glass board.

With this structure, the metal plated layers 109 can be located regardless of the number of the positions of the bumps 106, and the regions of the signal processing circuits 108 can be effectively used. This improves flexibility of the circuit layout to enable miniaturization of a chip size, which in turn enables further miniaturization of a package size. Furthermore, since the buffer portions do not contain adhesive of an organic material, deformation of the inside of the package due to blue-violet laser light for BDs.

In the above description, passive elements and active elements are not provided in the regions for providing the sealing portion and the buffer portions on the semiconductor substrate 101. Clearly, however, elements not shifting characteristics caused by stress due to effort for the circuit layout, elements not influencing characteristics of the entire optical semiconductor device 150 even when the characteristics are shifted, and aluminum interconnections may be provided in the regions for providing the sealing portion and the buffer portions.

The buffer portions (the metal plated layers 109) may be provided in any number and in any positions of the hollow region 105, as long as the semiconductor substrate 101 is not damaged by the load of the testing probe 200. Moreover, the buffer portions may be provided in positions being in contact with the sealing portion, or partially overlapping the sealing portion.

### Third Embodiment

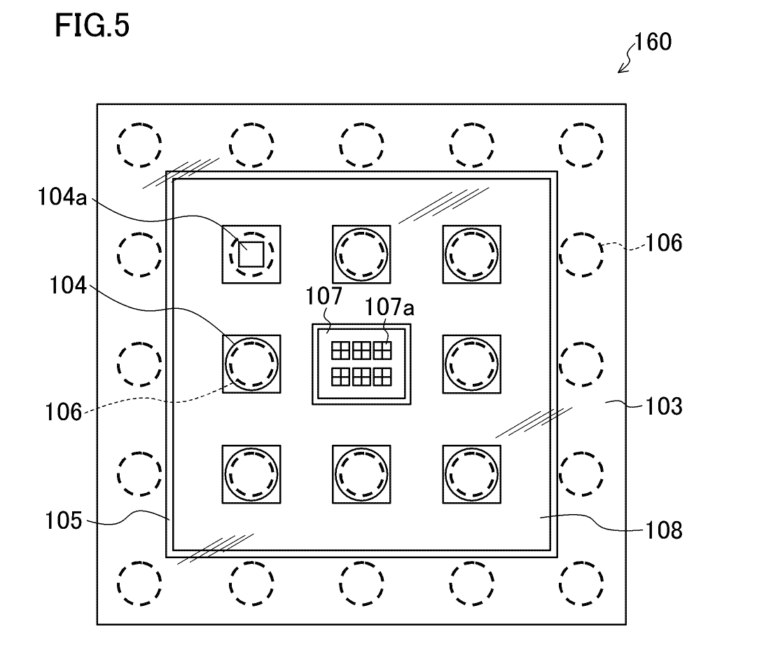

FIGS. 5, 6, 7, and 8 are top views illustrating the optical semiconductor device according to a third embodiment of the present disclosure. This embodiment differs from the first embodiment in part of the buffer portions or part of the sealing portion.

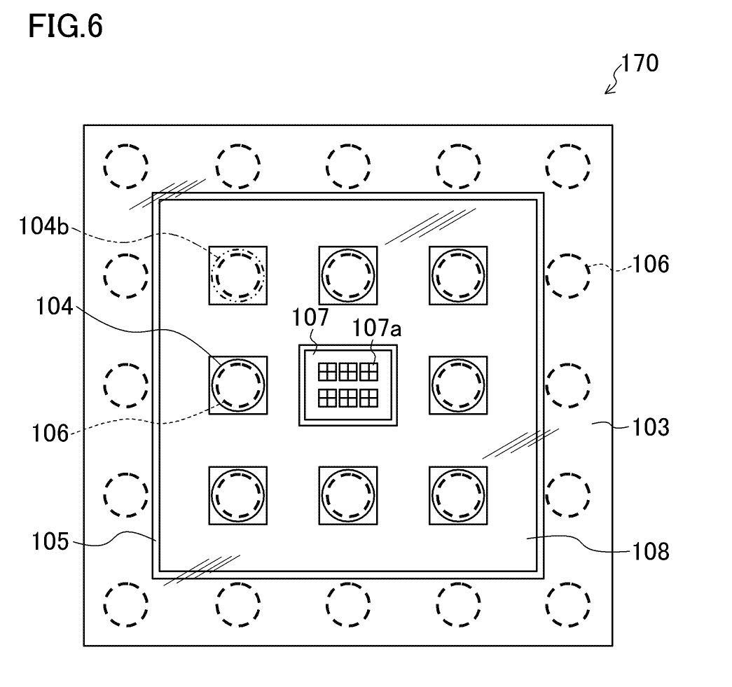

A buffer portion 104a shown in an optical semiconductor device 160 of FIG. 5 has a smaller size than the other buffer portions 104. While the other buffer portions 104 are circles, the buffer portion 104a is a square. In a buffer portion 104b shown in an optical semiconductor device 170 of FIG. 6, the buffer portion itself is removed. Since the forms and positions of the two buffer portions 104a and 104b differ from those of the other buffer portions 104, positions are easily recognized when the optical semiconductor devices 160 and 170 are seen from the front surfaces. For example, by providing the buffer portions 104a and 104b in close portions to a terminal of No. 1, the package directions of the optical semiconductor devices 160 and 170 can be easily recognized.

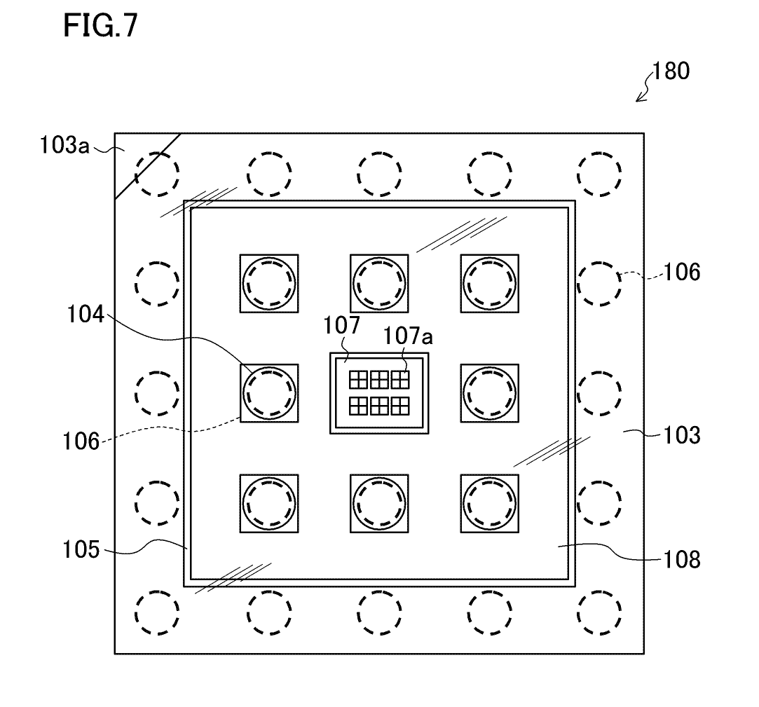

A sealing portion 103a of an optical semiconductor device 180 shown in FIG. 7 has a different form from the other three corners of the sealing portion 103. Thus, as well as the arrangement of the above-described buffer portions, positions can be easily recognized when the optical semiconductor device 180 is seen from the front surface. For example, by providing the sealing portion 103a in a close portion to a terminal of No. 1, the package direction of the optical semiconductor device 180 can be easily recognized.

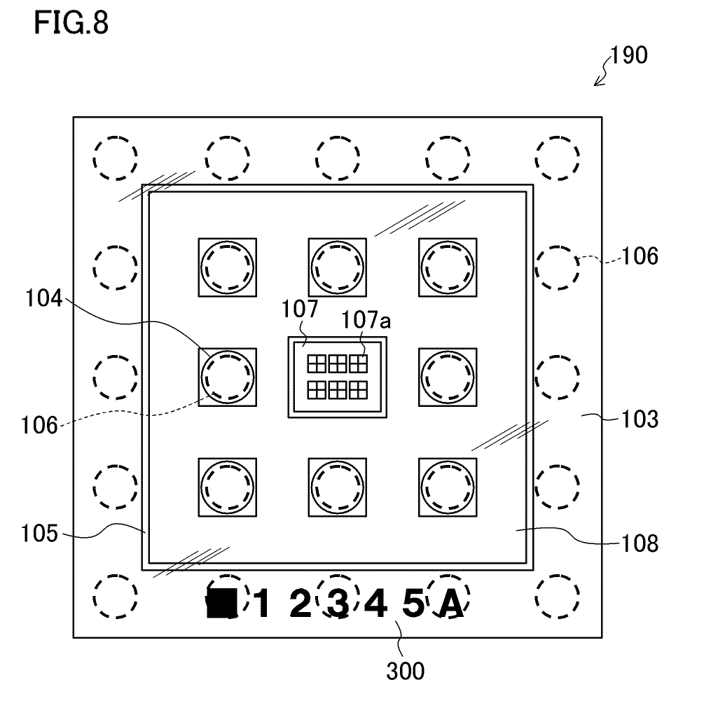

Furthermore, as shown in FIG. 8, by providing a mark 300 in the sealing portion 103 with a laser marker etc., the mark 300 is formed between the semiconductor substrate and the glass board. Thus, the mark is not faded or removed by damages in washing, reflow, etc., and the mark is clearly seen, and the package direction of the optical semiconductor device 190 can be easily recognized when the optical semiconductor device 190 is seen from the front surface at the position of the mark. Moreover, the mark 300 is formed by combining graphics, characters, and numbers to form identification numbers on individual optical semiconductor devices. Individual information such as model numbers and manufacturing dates can be separately formed.

### Fourth Embodiment

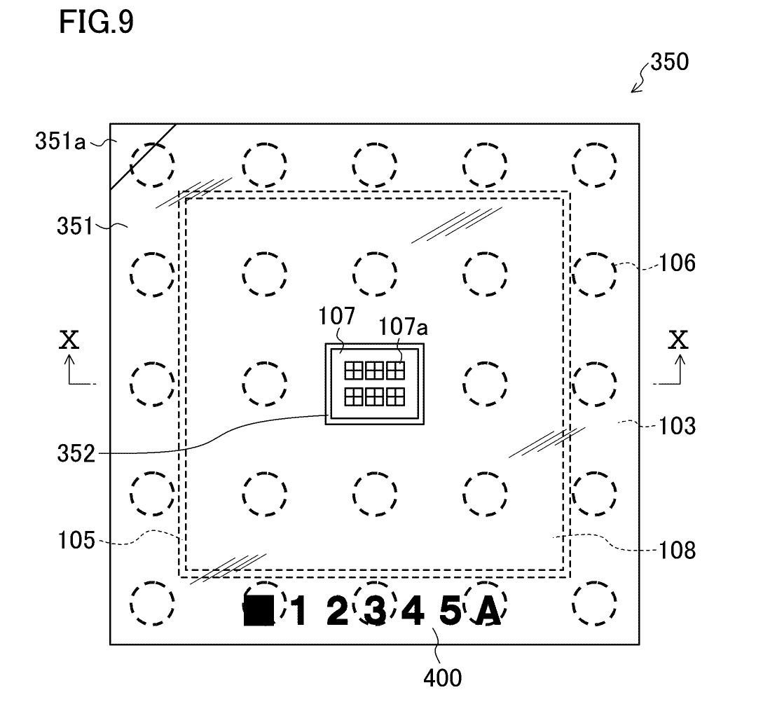

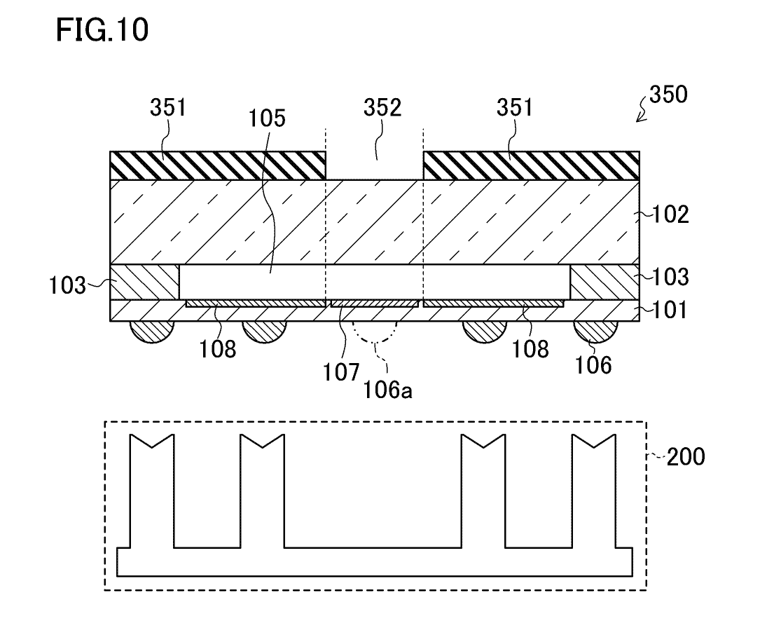

FIGS. 9 and 10 illustrate an optical semiconductor device according to a fourth embodiment of the present disclosure. Different from the first embodiment, an elastic body portion is provided on the surface of an optical semiconductor device instead of the buffer portions.

For example, in image sensors etc., buffer portions cannot be provided in a hollow region as in the first embodiment, since a light-receiving region is wide. In this case, a shock absorber needs to be provided in an optical semiconductor device instead of buffer portions.

As shown in FIGS. 9 and 10, an optical semiconductor device 350 includes a semiconductor substrate 101, a glass board (light-transmissive member) 102, an adhesive layer 103 as a sealing portion, a rubber elastic body portion 351 as a shock absorber, and bumps 106 as electrode terminals.

A light-receiving region 107 and signal processing circuits 108 are formed in a surface (a first main surface) of the semiconductor substrate 101. A plurality of light-receiving elements 107a receiving optical signals and generating photocurrents are provided in the light-receiving region 107. The semiconductor substrate 101 is bonded to the glass board 102 in a peripheral portion of the semiconductor substrate 101 by the adhesive layer 103. A hollow region 105 is formed in a portion surrounded by the semiconductor substrate 101, the glass board 102, and the adhesive layer 103.

When the adhesive layer 103 is bonded onto the light-receiving region 107, light transmittance decreases due to optical characteristics of the adhesive layer 103. Alternately, when irradiating blue-violet laser light with a wavelength around 405 nm, physical properties of the adhesive layer 103 particularly changes to cause a change in color or deformation. Thus, the adhesive layer 103 is not preferably formed on the light-receiving region 107. Also, when the adhesive layer 103 is bonded onto the signal processing circuits 108, stress caused by curing the adhesive layer 103 shifts values of resistors and capacitors which are passive elements, thereby shifting characteristics of transistors and diodes which are active elements. It is thus also not preferable to form the adhesive layer 103 on the signal processing circuits 108. Therefore, in order to reduce degradation of the characteristics, the adhesive layer 103 is not bonded onto the light-receiving region 107 or the signal processing circuits 108, and the hollow region 105 is provided.

The elastic body portion 351, which includes an opening 352 above the light-receiving region 107 and at the position substantially same as the light-receiving region 107, is provided on the surface of the glass board 102. The reason why the opening 352 is provided above the light-receiving region 107 is that the elastic body portion 351 is not preferably formed above the light-receiving region 107, since particularly physical properties of the elastic body portion 351 changes to cause a change in color or deformation when light transmittance is reduced by optical characteristics of the elastic body portion 351 as the adhesive layer does, or when irradiating blue-violet laser light with a wavelength around 405 nm.

When testing the optical semiconductor device 350 having a CSP structure including the hollow region 105, a testing probe 200 is pressed on the bumps 106 provided on the back surface of the optical semiconductor device 350 to obtain electrical contact between the bumps 106 and the testing probe 200. Thus, the load (e.g., 50 grams per probe) of the testing probe 200 is applied to the bumps 106.

In FIG. 9, since eight bumps 106 are included in the hollow region 105, a load of 50 grams×8=400 grams in total is applied to the semiconductor substrate 101 in the hollow region 105. When the hollow region 105 applied with the load of 400 grams is supported only by the adhesive layer 103 formed in a peripheral portion of the semiconductor substrate 101, cracks occur in the semiconductor substrate 101 for lack of strength, or in a worst case, the semiconductor substrate 101 may be broken. In order to reduce the breakage due to the load of the testing probe 200, the rubber elastic body portion 351 is provided on the surface of the glass board 102, thereby reducing the load of the testing probe 200 by the entire optical semiconductor device 350. That is, the rubber elastic body portion 351 allows the semiconductor substrate 101 to have strength withstanding the load of the testing probe 200.

Since the surface of the glass board 102 is exposed at the position of the elastic body opening 352, the surface of the glass board 102 may be damaged by a foreign substance such as dust. Therefore, the elastic body portion 351 preferably has a thickness of 50 μm or more, which is larger than the size (tens μm) of dust adhered during a manufacturing process. When the elastic body portion 351 has a thickness of 50 μm or more, the surface of the optical semiconductor device 350 comes into contact with a manufacturing equipment, a tray, etc. to damage the surface of the glass board 102, even when dust is adhered to the surface of the glass board 102 in the elastic body opening 352.

The elastic body opening 352 is preferably formed directly before dicing the optical semiconductor device 350 into pieces. Specifically, after bonding the semiconductor substrate 101 to the glass board 102, an elastic body material is applied to the surface of the glass board 102, and in this state, from formation of through electrodes (not shown) to bump formation are performed. Before performing dicing at the end, masking and exposure are performed to form the elastic body opening 352, thereby protecting the glass board surface with the elastic body material after applying the elastic body material to the bump formation. This reduces adhesion of dust etc. to the glass board surface in the elastic body opening 352, and cleans dust adhered to other portions in a cleaning process after the formation of the elastic body opening 352.

The surface of the elastic body portion 351 is preferably roughened. When the optical semiconductor device 350 is incorporated into a set, and furthermore, when a holder covers the optical semiconductor device 350, the surface of the optical semiconductor device 350 (the surface of the elastic body portion 351) is bonded to the holder with adhesive. Therefore, the adhesion improves when the optical semiconductor device 350 has a rough surface as compared to a mirror surface.

Furthermore, since the elastic body portion 351 is provided in a portion other than the surface of the glass board 102 corresponding to the light-receiving region 107, the elastic body portion 351 has the function as a light-shielding film. Thus, irradiation of unnecessary light caused by stray light etc. to a portion other than the light-receiving region 107 can be reduced. This reduces malfunction of the circuit due to the unnecessary light and particularly reduces a change in physical properties of the adhesive layer 103, which causes a change in color and deformation. In this case, a color such as pigment, which is hard to transmit light, is preferably mixed into the elastic body material in advance.

The elastic body corner 351a shown in FIG. 9 has a different form from the other three corners of the elastic body portion 351. Thus, similar to the arrangement of the sealing portion in the third embodiment, positions can be easily recognized when the optical semiconductor device 350 is seen from the front surface. For example, by providing the elastic body corner 351a in a close portion to a terminal of No. 1, the package direction of the optical semiconductor device 350 can be easily recognized.

Furthermore, by providing a mark 400 in the elastic body portion 351 with a laser marker etc., the package direction of the optical semiconductor device 350 can be easily recognized when the optical semiconductor device 350 is seen from the front surface at the position of the mark. Moreover, the mark 400 is formed by combining graphics, characters, and numbers to form identification numbers on individual optical semiconductor devices. Individual information such as model numbers and manufacturing dates can be separately formed.

While an example has been described where the bumps 106 projecting from the substrate are used as CSP back surface terminals, flat terminals also provide similar advantages in view of reducing substrate breakage in probe testing.

### Fifth Embodiment

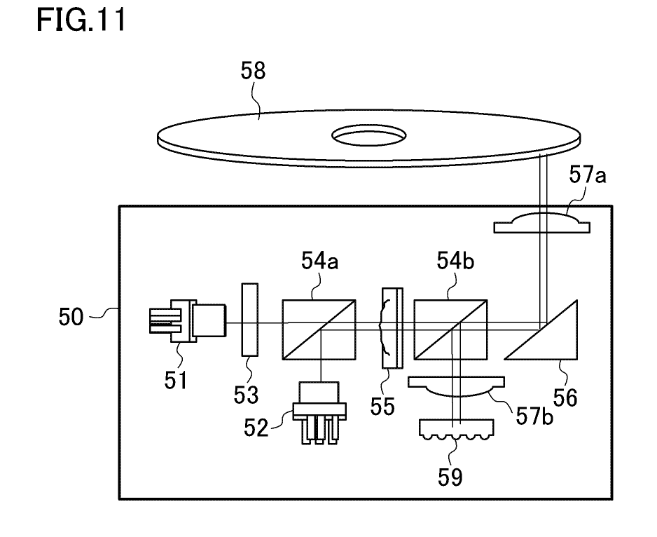

FIG. 11 illustrates the structure of an optical pickup device according to a fifth embodiment of the present disclosure. As shown in FIG. 11, an optical pickup device 50 reads information from an optical disc medium 58 such as a DVD and a CD and writing on the optical disc medium using laser light.

The optical pickup device 50 includes an infrared laser element 51 as a light source used for CDs, a red laser element 52 used for DVDs, a three-beam grating 53, a beam splitter 54a, a beam splitter 54b, a collimator 55, a mirror 56, objective lenses 57a and 57b, and a light-receiving IC 59.

In the optical pickup device 50, when the optical disc medium 58 is a CD, laser light emitted from the infrared laser element 51 is divided into three beam portions with the three-beam grating 53, sequentially passes through the beam splitter 54a, the collimator 55, and the beam splitter 54b, and is then reflected by the mirror 56 to enter the objective lens 57a. Then, after light collected by the objective lens 57a enters the optical disc medium (CD) 58 and is reflected, and the reflected light sequentially passes through the objective lens 57a, the mirror 56, and the beam splitter 54b, and returns. The direction of the reflected light from the optical disc medium 58 is bended by the beam splitter 54b and the reflected light passes through the objective lens 57b and is irradiated on the light-receiving surface of the light-receiving IC 59. The light-receiving IC 59 outputs information of the optical disc medium 58 as an electric signal.

In the light-receiving IC 59, a light-receiving element including a light-receiving portion (not shown) and a signal processing circuit amplifying a photocurrent generated at the light-receiving element are formed on a same silicon substrate. The light-receiving IC 59 is any one of the optical semiconductor devices described in the first to fourth embodiments.

The reflected light from the optical disc medium 58 includes pit information etc. on the surface of the optical disc medium 58. By processing the photocurrent generated at the light-receiving element; an information signal, a focus error signal, a tracking error signal, etc. of the optical disc medium 58 can be obtained. These signals are used for reading information of the optical disc medium 58 or controlling the position of the optical pickup device 50.

Therefore, the optical semiconductor devices of the first to fourth embodiments realize high reliability and miniaturization of the optical pickup device 50.

In the optical pickup device 50, when the optical disc medium 58 is a DVD, laser light emitted from the red laser element 52 passes through the beam splitter 54a, the collimator 55, and the beam splitter 54b, is reflected by the mirror 56, and enters the objective lens 57a. Then, after light collected by the objective lens 57a enters the optical disc medium (DVD) 58 and is reflected, and the reflected light sequentially passes through the objective lens 57a, the mirror 56, and the beam splitter 54b, and returns. The direction of the reflected light from the optical disc medium 58 is bended by the beam splitter 54b, and the reflected light passes through the objective lens 57b and is irradiated on the light-receiving surface of the light-receiving IC 59. The light-receiving IC 59 outputs information of the optical disc medium 58 as an electric signal.

As in the case of a CD, an electric signal caused by the reflected light from the optical disc medium 58 is used for reading information of the optical disc medium 58 and controlling the position of the optical pickup device 50. However, while laser light is divided into three beam portions where the optical disc medium 58 is a CD, the laser light is one beam portion where the optical disc medium 58 is a DVD. Reflected light from a CD and reflected light from a DVD are irradiated to different positions on a light-receiving portion. Therefore, in the light-receiving IC 59, a light-receiving portion used for obtaining information from a CD partially differs from a light-receiving portion used for obtaining information from a DVD.

In the optical pickup device 50, laser light emitted from the infrared laser element 51 and laser light emitted from the red laser element 52 are controlled so that the optical path from the beam splitter 54a to the optical disc medium 58 has a substantially same optical axis as the optical path from the optical disc medium 58 to the light-receiving IC 59. Therefore, regardless of whether the optical disc medium 58 is a CD or a DVD, a same optical element and a same optical system can be used, thereby facilitating miniaturization, control in assembling, etc. of the optical pickup device 50.

As described above, in the optical pickup device 50 of the fifth embodiment, the optical semiconductor devices of the first to fourth embodiments are used. Therefore, highly reliable and miniaturized optical pickup device can be realized.

Note that, in the optical pickup device 50, structures of the laser light sources, the light-receiving IC, etc. and positional relationship among the elements may be changed as appropriate in accordance with the design.

As such, the optical pickup device using the optical semiconductor device of the present disclosure has been described based on the embodiments, but is not limited thereto. For example, the optical semiconductor device of the present disclosure is preferably used for various electronic devices other than an optical pickup device. This realizes a highly reliable and miniaturized electronic device. Variations conceived by a skilled person within a range not deviating from the gist of the present disclosure are included in the present disclosure.

The present disclosure has been described using a light-transmissive member included in an optical semiconductor device. When the present disclosure is used as an interposer stacked on a semiconductor substrate, the optical semiconductor device does not necessarily include a light-transmissive member. A silicon substrate, a ceramic substrate, and a printing board are included in the present disclosure, as long as the range does not deviate from the gist of the present disclosure.

The present disclosure can be used for an optical semiconductor device, and an optical pickup device and an electronic device using the optical semiconductor device, particularly for an optical semiconductor device reading information from an optical disc medium, and an optical pickup device using the optical semiconductor device.

What is claimed is:

1. An optical semiconductor device comprising:
a semiconductor substrate including an active element on a first main surface;
a plurality of electrode terminals formed on another main surface of the semiconductor substrate;
a light-transmissive member provided on the first main surface to face the active element with a space interposed therebetween;
a sealing portion formed in a peripheral portion of the first main surface;
a hollow region formed on the first main surface among the active element, the light-transmissive member, and the sealing portion; and
buffer portions formed in at least one portion of the hollow region.

2. The optical semiconductor device of claim 1, wherein
an active element and a passive element are not formed in a region for providing the sealing portion on the first main surface of the semiconductor substrate.

3. The optical semiconductor device of claim 1, wherein
an active element and a passive element are not formed in a region for providing the buffer portions on the first main surface of the semiconductor substrate.

4. The optical semiconductor device of claim 1, wherein
the buffer portions are provided at regular intervals in the hollow region.

5. The optical semiconductor device of claim 1, wherein
the buffer portions are formed on the first main surface of the semiconductor substrate at positions facing at least one electrode terminal located on the other main surface of the semiconductor substrate.

6. The optical semiconductor device of claim 5, wherein
an area for providing the buffer portions on the first main surface of the semiconductor substrate is larger than an area of the at least one electrode terminal corresponding to the buffer portions, which is in contact with the other main surface of the semiconductor substrate.

7. The optical semiconductor device of claim 1, wherein
at least one of active elements formed on the semiconductor substrate is a light-receiving element outputting a photocurrent in accordance with an amount of incident light, and
no electrode terminal is formed directly below a position at which the light-receiving element is formed with the semiconductor substrate interposed therebetween.

8. The optical semiconductor device of claim 1, wherein
the sealing portion is formed of an adhesive layer.

9. The optical semiconductor device of claim 1, wherein
the sealing portion includes adhesive layers on and under a supporting body.

10. The optical semiconductor device of claim 1, wherein
the buffer portions are formed of adhesive layers.

11. The optical semiconductor device of claim 1, wherein
the buffer portions include adhesive layers on and under a supporting body.

12. The optical semiconductor device of claim 1, wherein
at least one of the buffer portions near a corner of the semiconductor substrate has a different form from the other buffer portions.

13. The optical semiconductor device of claim 1, wherein
no buffer portion is provided in a place for providing at least one of the buffer portions near a corner of the semiconductor substrate.

14. The optical semiconductor device of claim 1, wherein
at least one corner of the sealing portion near a corner of the semiconductor substrate has a different form from the other corners of the sealing portion.

15. The optical semiconductor device of claim 1, wherein
a mark is formed in the sealing portion.

16. The optical semiconductor device of claim 15, wherein
the mark includes any one of graphics, characters and numbers, or a combination of two or more of the graphics, characters and numbers.

17. An optical pickup device comprising the optical semiconductor device of claim 1.

18. An electronic device comprising the optical semiconductor device of claim 1.
